(19) United States
(12) Patent Application Publication
(10) Pub. No.: US 2006/0076581 A1
(43) Pub. Date: Apr. 13, 2006

(54) Solid-state image sensor

(75) Inventors: Masahiro Oda, Itami-shi (JP); Shinichiro Izawa, Motosu-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/231,805

(22) Filed: Sep. 22, 2005

(30) Foreign Application Priority Data
Oct. 7, 2004 (JP) 2004-294884

(51) Int. Cl. H01L 27/148

(52) U.S. Cl. 257/215

(57) ABSTRACT

A solid-state image sensor capable of suppressing increase of a dark current and a power consumption, and suppressing reduction of a transfer efficiency of electrons is provided. The solid-state image sensor comprises a charge storage region including a first conductive type first impurity region that has a first depth from a main surface of a semiconductor substrate, a first conductive type second impurity region that has a second depth larger than the first depth and an impurity concentration lower than an impurity concentration of the first impurity region, and a first conductive type third impurity region that has a third depth larger than the first depth and smaller than the second depth.

### BACKGROUND OF THE INVENTION

1. Field of the Invention

The present invention relates to a solid-state image sensor, and more particularly to a solid-state image sensor comprising an impurity region formed on a semiconductor substrate.

2. Description of the Background Art

A solid-state image sensor comprising an impurity region formed on a semiconductor substrate is known in general. This type of solid-state image sensor is disclosed in Japanese Patent Laying-Open No. 2001-291859, for example.

In the solid-state image sensor disclosed in the aforementioned Japanese Patent Laying-Open No. 2001-291859, an n-type impurity region (charge storage region) for forming a potentially concave portion that stores electrons in a region at a prescribed depth from the surface of the semiconductor substrate is formed, and an n⁺-type impurity region with an impurity concentration higher than an impurity concentration of the n-type impurity region is formed in a region in a depth smaller than the n-type impurity region. Accordingly, the depth of the potentially concave portion is increased, thus, a storage amount of electrons is increased. That is, in the aforementioned Japanese Patent Laying-Open No. 2001-291859, a charge storage region is composed of two impurity regions of the n-type impurity region formed in the surface of the semiconductor substrate and the n⁺-type impurity region, and the n⁺-type impurity region with a higher impurity concentration is located on the surface side of the semiconductor substrate. In the solid-state image sensor disclosed in the aforementioned Japanese Patent Laying-Open No. 2001-291859, when electrons are transferred, recombination between electrons and holes that exist in the vicinity of the surface of the semiconductor substrate may reduce a transfer efficiency of electrons. In this case, since increasing the impurity concentration of at least one of the n-type and n⁺-type impurity regions can space the potentially concave portion that stores electrons more deeply away from the surface of the semiconductor substrate, when electrons are transferred, recombination between electrons and holes that exist in the vicinity of the surface of the semiconductor substrate is suppressed. Consequently, reduction of a transfer efficiency of electrons is suppressed.

However, in the solid-state image sensor disclosed in the aforementioned Japanese Patent Laying-Open No. 2001-291859, in the case where an impurity concentration of the n⁺-type impurity region located on the surface side (shallower side) of the semiconductor substrate is increased, since a potential of the surface of the semiconductor substrate is increased due to increase of an impurity concentration of the surface of the semiconductor substrate, there is a disadvantage that increases an electric field that appears in the surface of the semiconductor substrate due to a gate voltage. In this case, the electric field in the surface of the semiconductor substrate pulls out more electrons that are thermally excited, thus, there is a problem that a dark current is increased. Additionally, in the solid-state image sensor disclosed in the aforementioned Japanese Patent Laying-Open No. 2001-291859, in the case where an impurity concentration of the n-type impurity region located on the opposite side (deeper side) to the surface of the semiconductor substrate is increased, since a potentially concave portion with a large curvature and a large width is formed, there is a disadvantage that requires a large gate voltage to transfer electrons stored in the potentially concave portion. In this case, there is a problem that a power consumption is increased.

### SUMMARY OF THE INVENTION

The present invention is aimed at solving the above problems, and it is one object of the present invention to provide a solid-state image sensor capable of suppressing increase of a dark current and a power consumption, and suppressing reduction of a transfer efficiency of electrons.

To achieve the above object, a solid-state image sensor according to a first aspect of the present invention comprises a semiconductor substrate; and a charge storage region including a first conductive type first impurity region that has a first depth from a main surface of the semiconductor substrate, a first conductive type second impurity region that has a second depth larger than the first depth of the first impurity region and an impurity concentration lower than an impurity concentration of the first impurity region, and a first conductive type third impurity region that has a third depth larger than the first depth of the first impurity region of the semiconductor substrate and smaller than the second depth of the second impurity region.

In the solid-state image sensor according to this first aspect, as mentioned above, the first conductive type third impurity region that has the third depth larger than the first depth of the first impurity region of the semiconductor substrate and smaller than the second depth of the second impurity region is provided in the charge storage region. As a result, since a first conductive type impurity concentration of the charge storage region can be increased as compared with the case where the third impurity region is not provided, it is possible to space a potentially concave portion that stores electrons more deeply away from the main surface of the semiconductor substrate. Accordingly, since, when electrons are transferred, recombination between electrons and holes that exist in the vicinity of the main surface of the semiconductor substrate can be suppressed, it is possible to suppress reduction of transfer efficiency of electrons. In addition, since the first conductive type impurity concentration of the charge storage region is increased by forming the third impurity region in a region deeper than the first impurity region of the semiconductor substrate, it is possible to suppress increase of an impurity concentration in the main surface of the semiconductor substrate as compared with the case where the first conductive type impurity concentration of the charge storage region is increased by increasing the impurity concentration of the first impurity region located on the main surface side (shallower side) of the semiconductor substrate. Accordingly, since increase of a potential of the main surface of the semiconductor substrate can be suppressed as compared with the case where the impurity concentration of the first impurity region is increased, it is possible to suppress increase of an electric field that appears in the main surface of the semiconductor substrate due to a gate voltage. Therefore, since increase of an amount of electrons that are thermally excited and pulled out due to the electric field in the main surface of the semiconductor substrate can be suppressed, it is possible to suppress increase of a dark current. Additionally, since the first conductive type impurity concentration of the charge storage region is increased by forming the third impurity region in a region shallower than the second impurity region of the semiconductor substrate, it is possible to suppress increase of a curvature and a width of a potentially concave portion that stores electrons as compared with the case where the first conductive type impurity concentration of the charge storage region is increased by increasing the impurity concentration of the second impurity region deeper than the third impurity region. Therefore, since increase of a gate voltage necessary to transfer the electrons stored in the potentially concave portion can be suppressed, it is possible to suppress increase of a power consumption.

In the aforementioned solid-state image sensor according to the first aspect, preferably, the charge storage region including the first, second and third impurity regions is formed in an imaging part. In this constitution, in the imaging part, it is possible to suppress increase of a dark current and a power consumption, and to suppress reduction of a transfer efficiency of electrons.

In the aforementioned solid-state image sensor according to the first aspect, preferably, the third impurity region has an impurity concentration lower than the impurity concentration of the first impurity region and higher than the impurity concentration of the second impurity region. In this constitution, since the third impurity region having a depth larger than the depth of the first impurity region is configured to have an impurity concentration lower than the impurity concentration of the first impurity region, it is possible to easily suppress increase of an impurity concentration in the main surface of the semiconductor substrate. In addition, since the third impurity region having a depth smaller than the depth of the second impurity region is configured to have an impurity concentration higher than the impurity concentration of the second impurity region, it is possible to easily suppress increase of a curvature and a width of a potentially concave portion that stores electrons. In this case, the first, second and third impurity regions can have the n-type conductivity, and the third impurity region can have an n-type impurity concentration lower than the n-type impurity concentration of the first impurity region and higher than the n-type impurity concentration of the second impurity region.

In the aforementioned solid-state image sensor according to the first aspect, preferably, the third impurity region has the maximum impurity concentration in the main surface of the semiconductor substrate. In this constitution, as compared with the case where the third impurity region has the maximum impurity concentration in a location deeper than the main surface of the semiconductor substrate, it is possible to further suppress increase of a curvature and a width of a potentially concave portion that stores electrons.

In the aforementioned solid-state image sensor according to the first aspect, preferably, the sensor further comprises a plurality of second conductive type channel stop regions formed in the semiconductor substrate to make a separation into a plurality of pixels, and the first conductive type first and third impurity regions are formed in a region of the semiconductor substrate other than the second conductive type channel stop regions. In this constitution, when the first and third impurity regions are formed, it is possible to suppress introduction of the first conductive type impurities of the first and third impurity regions into the second conductive type channel stop regions. Accordingly, since reduction of height of a potential barrier between pixels adjacent to each other that interpose the channel stop region between them due to introduction of the first conductive type impurities into the second conductive type channel stop region can be suppressed, it is possible to suppress movement of electrons from a prescribed pixel into other adjacent pixel through the channel stop region.

In the aforementioned solid-state image sensor including the channel stop region, preferably, the first conductive type third impurity region is formed between the first conductive type first impurity region and the second conductive type channel stop region. In this constitution, the first conductive type third impurity region can reduce an electric field applied from the second conductive type channel stop region to the first conductive type charge storage region. Accordingly, since a phenomenon of reduction of a channel width due to an electric field from the second conductive type channel stop region (narrow channel effect) can be suppressed, it is possible to further suppress reduction of a transfer efficiency of electrons.

In the aforementioned solid-state image sensor including the channel stop region, the second depth of the first conductive type second impurity region can be larger than a depth of the second conductive type channel stop region, and the first conductive type second impurity region can be formed not only in a region of the semiconductor substrate where the first and third impurity regions are formed but also in regions of the semiconductor substrate where the second conductive type channel stop regions are formed.

In the aforementioned solid-state image sensor including the channel stop region, preferably, the plurality of the second conductive type channel stop regions are formed so as to extend along a transfer direction of charge and to be spaced at a prescribed interval in a direction that intersects the transfer direction of charge, and the first conductive type first, second and third impurity regions are formed in a region between the channel stop regions adjacent to each other so as to extend along the transfer direction of charge. In this constitution, the first, second and third impurity regions that are formed so as to extend along the transfer direction of charge can effectively suppress reduction of a transfer efficiency of electrons.

In the aforementioned solid-state image sensor including the channel stop region, preferably, the sensor further comprises a plurality of transfer electrodes that are formed so as to be spaced at a prescribed interval from each other in a transfer direction of charge in regions where the first, second and third impurity regions in the main surface of the semiconductor substrate, and the channel stop regions are formed. In this constitution, when the transfer electrodes transfer electrons, the first, second and third impurity regions can suppress reduction of a transfer efficiency of electrons.

In the aforementioned solid-state image sensor according to the first aspect, preferably, the mass number of a first conductive type impurity contained in the third impurity region is smaller than the mass number of a first conductive type impurity contained in the first impurity region. In this constitution, since the first conductive type impurities contained in the third impurity region tend to thermally diffuse than the first conductive type impurities contained in the first impurity region, when heat treatment is conducted after the first conductive type impurities contained in the first impurity region and the first conductive type impurities contained in the third impurity region are introduced in the same region of the semiconductor substrate, it is possible to easily form the third impurity region in a region of the semiconductor substrate deeper than the first impurity region.

In this case, the first conductive type impurity contained in the third impurity region can be P (phosphorus), and the first conductive type impurity contained in the first impurity region can be As.

In the aforementioned solid-state image sensor according to the first aspect, preferably, the semiconductor substrate has a first conductivity, and a second conductive type fourth impurity region formed so as to have a fourth depth from the main surface of the semiconductor substrate larger than the second depth of the second impurity region of the charge storage region is provided in the main surface of the first conductive type semiconductor substrate, wherein the first conductive type first, second and third impurity regions are formed in a main surface of the second conductive type fourth impurity region. In this constitution, it is possible to pull out electrons that overflow from potential wells of the first through third impurity regions storing electrons through the second conductive type fourth impurity region toward the first conductive type semiconductor substrate side.

A solid-state semiconductor substrate according to a second aspect of the present invention comprises an n-type semiconductor substrate; a charge storage region including an n-type first impurity region that has a first depth from a main surface of the n-type semiconductor substrate, an n-type second impurity region that has a second depth larger than the first depth of the n-type first impurity region and an impurity concentration lower than an impurity concentration of the n-type first impurity region, and an n-type third impurity region that has a third depth larger than the first depth of the n-type first impurity region and smaller than the second depth of the n-type second impurity region; and a p-type fourth impurity region formed in the main surface of the n-type semiconductor substrate so as to have a fourth depth from the main surface of the n-type semiconductor substrate larger than the second depth of the second impurity region of the charge storage region.

In the solid-state image sensor according to this second aspect, as mentioned above, the n-type third impurity region that has the third depth larger than the first depth of the n-type first impurity region of the semiconductor substrate and smaller than the second depth of the n-type second impurity region is provided in the charge storage region. As a result, since an n-type impurity concentration of the charge storage region can be increased as compared with the case where the n-type third impurity region is not provided, it is possible to space a potentially concave portion that stores electrons more deeply away from the main surface of the semiconductor substrate. Accordingly, since, when electrons are transferred, recombination between electrons and holes that exist in the vicinity of the main surface of the semiconductor substrate can be suppressed, it is possible to suppress reduction of transfer efficiency of electrons. In addition, since the n-type impurity concentration of the charge storage region is increased by forming the n-type third impurity region in a region deeper than the n-type first impurity region, it is possible to suppress increase of an n-type impurity concentration in the main surface of the semiconductor substrate as compared with the case where the n-type impurity concentration of the charge storage region is increased by increasing the impurity concentration of the first impurity region located on the main surface side (shallower side) of the semiconductor substrate. Accordingly, since increase of a potential of the main surface of the semiconductor substrate can be suppressed as compared with the case where the n-type impurity concentration of the first impurity region is increased, it is possible to suppress increase of an electric field that appears in the main surface of the semiconductor substrate due to a gate voltage. Therefore, since increase of an amount of electrons that are thermally excited and pulled out due to the electric field in the main surface of the semiconductor substrate can be suppressed, it is possible to suppress increase of a dark current. Additionally, since the n-type impurity concentration of the charge storage region is increased by forming the third impurity region in a region shallower than the second impurity region of the semiconductor substrate, it is possible to suppress increase of a curvature and a width of a potentially concave portion that stores electrons as compared with the case where the n-type impurity concentration of the charge storage region is increased by increasing the impurity concentration of the n-type second impurity region deeper than the third impurity region. Therefore, since increase of a gate voltage necessary to transfer the electrons stored in the potentially concave portion can be suppressed, it is possible to suppress increase of a power consumption.

Additionally, in the aforementioned second aspect, the p-type fourth impurity region formed in the main surface of the n-type semiconductor substrate so as to have a fourth depth from the main surface of the n-type semiconductor substrate larger than the second depth of the second impurity region of the charge storage region is provided, thus, it is possible to provide a structure having the first conductive type first through third impurity regions that are formed in the main surface of the second conductive type fourth impurity region formed in the main surface of the n-type semiconductor substrate. Therefore, it is possible to pull out electrons that overflow from potential wells of the first through third impurity regions storing electrons through the second conductive type fourth impurity region toward the first conductive type semiconductor substrate side.

### BRIEF DESCRIPTION OF THE DRAWINGS

FIG. 1 is a view schematically showing the whole constitution of a solid-state image sensor according to one embodiment of the present invention;

FIG. 2 is a plan view for illustrating a structure of an imaging part and a storage part of the solid-state image sensor according to the one embodiment shown in FIG. 1;

FIG. 3 is a cross-sectional view of the imaging part of the solid-state image sensor taken along a line 50-50 shown in FIG. 2;

FIG. 4 is a cross-sectional view of the imaging part of the solid-state image sensor taken along a line 100-100 shown in FIG. 2;

FIG. 5 is a cross-sectional view for illustrating a manufacturing process of the solid-state image sensor according to one embodiment of the present invention;

FIG. 6 is a cross-sectional view for illustrating a manufacturing process of the solid-state image sensor according to the one embodiment of the present invention;

FIG. 7 is a cross-sectional view for illustrating a manufacturing process of the solid-state image sensor according to the one embodiment of the present invention;

FIG. 8 is a cross-sectional view for illustrating a manufacturing process of the solid-state image sensor according to the one embodiment of the present invention;

FIG. 9 is a cross-sectional view for illustrating a manufacturing process of the solid-state image sensor according to the one embodiment of the present invention;

FIG. 10 is a correlation diagram showing change of each potential of solid-state image sensors according to an example and a comparative example against a depth from the surface of an n-type silicon substrate;

FIG. 11 is a correlation diagram showing change of each impurity concentration of the solid-state image sensors according to the example and the comparative example against a depth from the surface of the n-type silicon substrate;

FIG. 12 is a correlation diagram showing change of each impurity concentration of an n⁺-type impurity region, an n-type intermediate impurity region and an n-type impurity region against a depth from the surface of the n-type silicon substrate; and

FIG. 13 is a correlation diagram showing change of each potential of the n-type silicon substrate surface in the case where impurity concentrations of the n⁺-type impurity region, the n-type intermediate impurity region and the n-type impurity region are varied.

### DESCRIPTION OF THE PREFERRED EMBODIMENT

An embodiment of the present invention is now described with reference to the drawings.

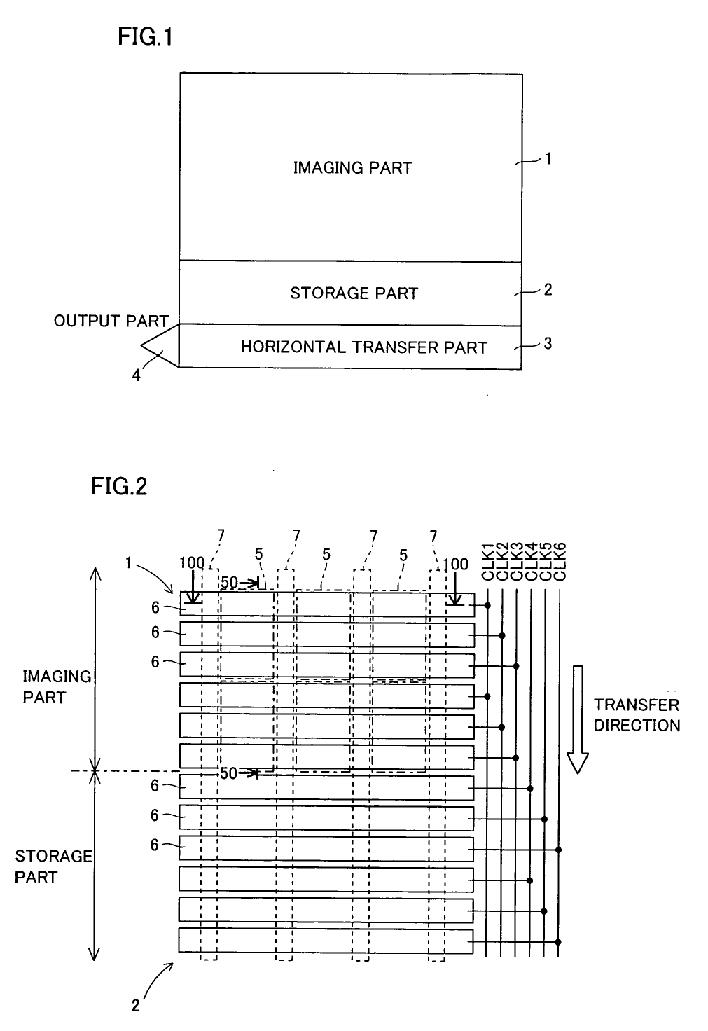

With reference to FIGS. 1 to 4, in this embodiment, an exemplary frame transfer type solid-state image sensor to which the present invention is applied is described.

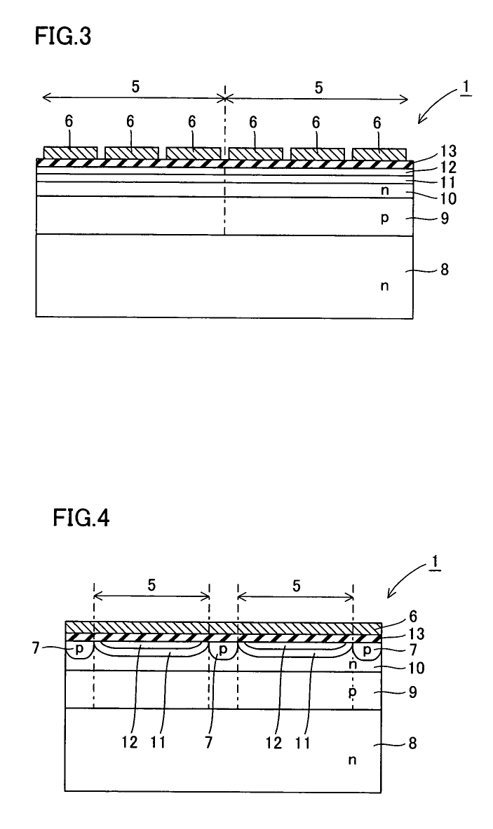

The frame transfer type solid-state image sensor according to this embodiment comprises an imaging part 1, a storage part 2, a horizontal transfer part 3, and an output part 4, as shown in FIG. 1. The imaging part 1 is provided to perform photoelectric conversion from light incident thereon. The imaging part 1 has a plurality of pixels 5 that serve to perform photoelectric conversion and are arranged in a matrix shape, as shown in FIG. 2. The imaging part 1 serves to store electrons (charge) produced due to photoelectric conversion and to transfer the electrons to the storage part 2. The storage part 2 serves to store the electrons transferred from the imaging part 1 and to transfer the electrons to the horizontal transfer part 3 (see FIG. 3). The horizontal transfer part 3 serves to sequentially transfer the electrons transferred from the storage part 2 to the output part 4. The output part 4 serves to provide the electrons transferred from the horizontal transfer part 3 as an electrical signal.

In the imaging part 1 and the storage part 2, as shown in FIG. 2, a plurality of gate electrodes 6 with a width of about 0.4 μm are provided so as to be spaced at an interval of about 0.6 μm from each other. In addition, three gate electrodes 6 are provided in each one pixel 5. While three-phase clock signals CLK1 to CLK3 for transferring electrons are provided to the three gate electrodes 6 of the imaging part 1, respectively, three-phase clock signals CLK4 to CLK6 for transferring electrons are provided to the three gate electrodes 6 of the storage part 2, respectively. The imaging part 1 is configured such that these three-phase clock signals CLK1 to CLK3 turn the three gate electrodes 6 in the same pixel 5 to ON state one time each, and thus sequentially transfer electrons that are stored in a region under a prescribed gate electrode 6 in the same pixel 5 to regions under gate electrodes 6 other than the prescribed gate electrode 6 in the same pixel 5. Additionally, a p-type channel stop region 7 is provided so as to extend along a transfer direction of electrons between two pixels 5 that are located adjacent to each other along a direction perpendicular to the transfer direction of electrons.

As shown in FIGS. 3 and 4, a p-type impurity region 9 that has a depth of about 2 μm to about 4 μm from the surface of an n-type silicon substrate 8 and an impurity concentration of about 10¹⁵ cm⁻³ is formed in the imaging part 1. The n-type silicon substrate 8 is an example of a “semiconductor substrate” in the present invention. In addition, an n-type impurity region 10 that has a depth of about 0.5 μm to about 1.0 μm from the surface of the n-type silicon substrate 8 and an impurity concentration (peak concentration) of about 5×10¹⁵ cm⁻³ to about 5×10¹⁶ cm⁻³ is formed. The n-type impurity region 10 is an example of a “second impurity region” in the present invention. Additionally, as shown in FIG. 4, a plurality of the p-type channel stop regions 7 are formed so as to be spaced at a prescribed interval from each other in the surface of the n-type impurity region 10.

In this embodiment, an n-type intermediate impurity region 11 that has a depth of about 0.3 μm to about 0.5 μm from the surface of the n-type silicon substrate 8 and an impurity concentration (peak concentration) of about 10¹⁶ cm⁻³ to about 10¹⁷ cm⁻³ is formed between two p-type channel stop regions 7 adjacent to each other. In addition, an n⁺-type impurity region 12 that has a depth of about 0.1 μm to about 0.3 μm from the surface of the n-type silicon substrate 8 and an impurity concentration (peak concentration) of about 10¹⁷ cm⁻³ to about 10¹⁸ cm⁻³ is formed between two p-type channel stop regions 7 adjacent to each other.

That is, in this embodiment, the n-type intermediate impurity region 11 is formed in a region deeper than the n⁺-type impurity region 12 and shallower than the n-type impurity region 10, and has the impurity concentration (about 10¹⁶ cm⁻³ to about 10¹⁷ cm⁻³) lower than the impurity concentration (about 10¹⁷ cm⁻³ to about 10¹⁸ cm⁻³) of the n⁺-type impurity region 12 and higher than the impurity concentration (about 5×10¹⁵ cm⁻³ to about 5×10¹⁶ cm⁻³) of the n-type impurity region 10. In this embodiment, the n-type impurity region 10, the n-type intermediate impurity region 11 and the n⁺-type impurity region 12 compose an n-type charge storage region. The n-type intermediate impurity region 11 is an example of a “third impurity region”. The n⁺-type impurity region 12 is an example of a “first impurity region”.

In this embodiment, while the n⁺-type impurity region 12 contains As (arsenic) as an n-type impurity, the n-type impurity region 10 and the n-type intermediate impurity region 11 contain P (phosphorus) that has a mass number smaller than As (arsenic) as an n-type impurity. The n-type intermediate impurity region 11 is configured to have the maximum impurity concentration in the surface of the n-type silicon substrate 8. Additionally, the n-type intermediate impurity region 11 is formed to surround the n⁺-type impurity region 12, and is formed to be in contact with the side surface of the p-type channel stop region 7. Thus, the n-type intermediate impurity region 11 is formed in a region between the n⁺-type impurity region 12 and the p-type channel stop region 7. The n-type silicon substrate 8, the p-type impurity region 9, the n-type impurity region 10, the n-type intermediate impurity region 11 and the n⁺-type impurity region 12 compose a vertical overflow drain structure that carries off electrons overflowing from a potentially concave portion storing electrons toward the n-type silicon substrate 8 side. A gate insulating film 13 consisting of SiO₂ is formed on the p-type channel stop region 7, the n-type intermediate impurity region 11 and the n⁺-type impurity region 12 of the n-type silicon substrate 8. The aforementioned plurality of gate electrodes 6 are formed on the gate insulating film 13. The storage part 2 (see FIG. 2) has a structure similar to the aforementioned imaging part 1.

In this embodiment, the n-type intermediate impurity region 11 that has a depth larger than the depth of the n⁺-type impurity region 12 and smaller than the depth of the n-type impurity region 10, and an impurity concentration lower than the impurity concentration of the n⁺-type impurity region 12 and higher than the impurity concentration of the n-type impurity region 10 is provided in the charge storage region of the imaging part 1 and the storage part 2 as mentioned above. As a result, since an n-type impurity concentration of the charge storage region can be increased as compared with the case where the n-type intermediate impurity region 11 is not provided, it is possible to space the potentially concave portion that stores electrons more deeply away from the surface of the n-type silicon substrate 8. Accordingly, since, when electrons are transferred, recombination between electrons and holes that exist in the vicinity of the surface of the n-type silicon substrate 8 can be suppressed, it is possible to suppress reduction of transfer efficiency of electrons.

Additionally, in this embodiment, since the n-type impurity concentration of the charge storage region is increased by forming the n-type intermediate impurity region 11 in a region deeper than the n⁺-type impurity region 12 of the n-type silicon substrate 8 that has an impurity concentration lower than the impurity concentration of the n⁺-type impurity region 12, it is possible to suppress increase of an impurity concentration in the surface of the n-type silicon substrate 8 as compared with the case where the n-type impurity concentration of the charge storage region is increased by increasing the impurity concentration of the n⁺-type impurity region 12 located on the surface side (shallower side) of the n-type silicon substrate 8. Accordingly, since increase of a potential of the surface of the n-type silicon substrate 8 can be suppressed as compared with the case where the impurity concentration of the n⁺-type impurity region 12 is increased, it is possible to suppress increase of an electric field that appears in the surface of the n-type silicon substrate 8 due to a gate voltage. Therefore, since increase of an amount of electrons that are thermally excited and pulled out due to the electric field of the surface of the n-type silicon substrate 8 can be suppressed, it is possible to suppress increase of a dark current.

Additionally, in this embodiment, since the n-type impurity concentration of the charge storage region is increased by forming the n-type intermediate impurity region 11 in a region shallower than the n-type impurity region 10 of the n-type silicon substrate 8 that has an impurity concentration higher than the impurity concentration of the n-type impurity region 10, it is possible to suppress increase of a curvature and a width of a potentially concave portion that stores electrons as compared with the case where the n-type impurity concentration of the charge storage region is increased by increasing the impurity concentration of the n-type impurity region 10 deeper than the n-type intermediate impurity region 11. Therefore, since increase of a gate voltage necessary to transfer the electrons stored in the potentially concave portion can be suppressed, it is possible to suppress increase of a power consumption.

In this embodiment, since the n-type intermediate impurity region 11 is formed in a region between the n⁺-type impurity region 12 and the p-type channel stop region 7, it is possible to reduce an electric field applied from the p-type channel stop region 7 to the n-type charge storage region. Accordingly, since a phenomenon of reduction of a channel width due to an electric field from the p-type channel stop region 7 (narrow channel effect) can be suppressed, it is possible to further suppress reduction of a transfer efficiency of electrons.

A manufacturing process of the frame transfer type solid-state image sensor according to one embodiment of the present invention is described with reference to FIGS. 3 to 9.

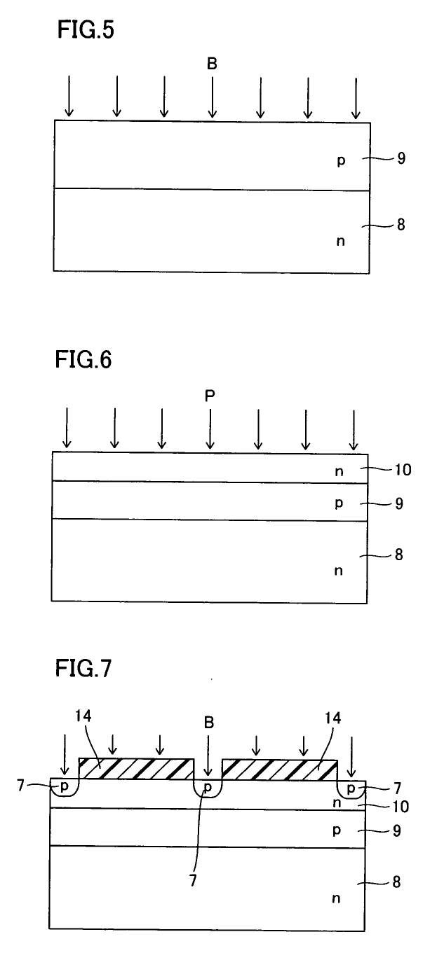

First, as shown in FIG. 5, B (boron) is introduced to the n-type silicon substrate 8 by ion implantation under conditions of implantation energy of about 60 keV to about 2000 keV, and a dose of about 1×10¹¹ cm⁻² to about 1×10¹² cm⁻². After that, heat treatment is conducted at a temperature of about 800° C. to about 1200° C. for about one hour to about ten hours, thus, B (boron) thermally diffuses and is electrically activated. As a result, the p-type impurity region 9 that has a depth of about 2 μm to about 4 μm from the surface of the n-type silicon substrate 8 and an impurity concentration of about 10¹⁵ cm⁻³ is formed.

Subsequently, as shown in FIG. 6, P (phosphorus) is introduced to the n-type silicon substrate 8 by ion implantation under conditions of implantation energy of about 100 keV to about 200 keV, and a dose of about 1×10¹¹ cm⁻² to about 1×10¹² cm⁻². After that, heat treatment is conducted at a temperature of about 800° C. to about 1200° C. for about ten minutes to about five hours, thus, P (phosphorus) thermally diffuses and is electrically activated. As a result, the n-type impurity region 10 that has a depth of about 0.5 μm to about 1.0 μm from the surface of the n-type silicon substrate 8 and an impurity concentration of about 5×10¹⁵ cm⁻³ to about 5×10¹⁶ cm⁻³ is formed. Then, as shown in FIG. 7, a resist film 14 is formed so as to cover a region except regions where the p-type channel stop regions 7 are formed by photolithography. This resist film 14 serves as a mask, and B (boron) is introduced to the n-type silicon substrate 8 by ion implantation. Thus, the plurality of the p-type channel stop regions 7 are formed so as to be spaced at a prescribed interval from each other in prescribed regions of the n-type impurity region 10. After that, the resist film 14 is removed.

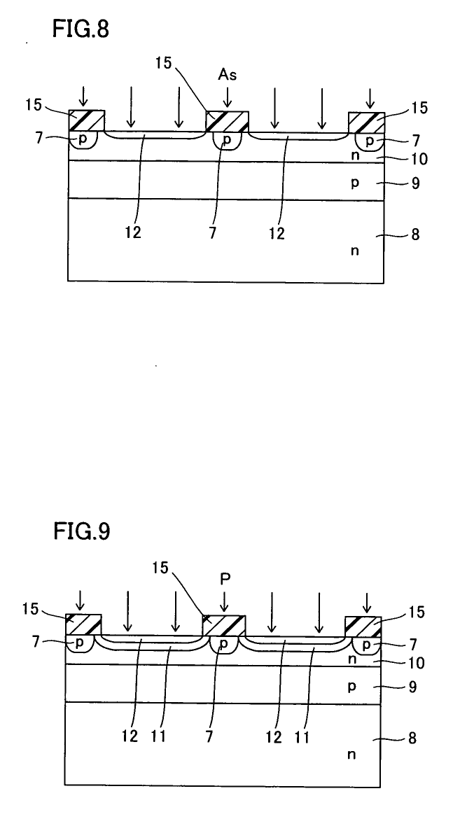

Then, in this embodiment, as shown in FIG. 8, a resist film 15 is formed so as to cover a region except regions where the n⁺-type impurity regions 12 are formed by photolithography. Subsequently, the resist film 15 serves as a mask, and As (arsenic) is introduced to the n-type silicon substrate 8 by ion implantation under conditions of implantation energy of about 40 keV to about 100 keV, and a dose of about 1×10¹² cm⁻² to about 1×10¹³ cm⁻². Subsequently, as shown in FIG. 9, the resist film 15 same as the process of FIG. 8 serves as a mask, and P (phosphorus) is introduced to the n-type silicon substrate 8 by ion implantation under conditions of implantation energy of about 40 keV to about 100 keV, and a dose of about 1×10¹¹ cm⁻² to about 1×12 cm⁻². After that, heat treatment is conducted at a temperature of about 800° C. to about 1200° C. for about ten minutes to about five hours, thus, introduced As (arsenic) and P (phosphorus) thermally diffuse and are electrically activated. Accordingly, the n⁺-type impurity region 12 that has a depth of about 0.1 μm to about 0.3 μm from the surface of the n-type silicon substrate 8 and an impurity concentration (peak concentration) of about 10¹⁷ cm⁻³ to about 10¹⁸ cm⁻³ is formed between two p-type channel stop regions 7 adjacent to each other. In addition, the n-type intermediate impurity region 11 that has a depth of about 0.3 μm to about 0.5 μm from the surface of the n-type silicon substrate 8 and an impurity concentration (peak concentration) of about 10¹⁶ cm⁻³ to about 10¹⁷ cm⁻³ is formed between two p-type channel stop regions 7 adjacent to each other. In the above heat treatment, since P (phosphorus) that has a mass number smaller than As (arsenic) tends to thermally diffuse, it thermally diffuses in a region deeper and wider than As (arsenic). As a result, the n-type intermediate impurity region 11 is formed to surround the n⁺-type impurity region 12, and is formed to be in contact with the side surface of the p-type channel stop region 7. Thus, the n-type intermediate impurity region 11 is formed in a region between the n⁺-type impurity region 12 and the p-type channel stop region 7. Additionally, in the heat treatment, since P (phosphorus) aggregates to the surface of the n-type silicon substrate 8, the impurity concentration of P (phosphorus) of the n-type intermediate impurity region 11 becomes the maximum in the surface of the n-type silicon substrate 8.

Finally, as shown in FIG. 3, after the gate insulating film 13 consisting of SiO₂ is formed so as to cover the whole surface by a CVD process, the plurality of gate electrodes 6 that have a width of about 0.4 μm are formed on the gate insulating film 13 so as to be spaced at an interval of about 0.6 μm from each other. As mentioned above, the frame transfer type solid-state image sensor according to this embodiment shown in FIGS. 3 and 4 is formed.

In this embodiment, as mentioned above, since the n⁺-type impurity region 12 and the n-type intermediate impurity region 11 are formed in regions of the n-type silicon substrate 8 except the p-type channel stop regions 7, in the ion implantation of As (arsenic) as an n-type impurity of the n⁺-type impurity region 12 and P (phosphorus) as an n-type impurity of the n-type intermediate impurity region 11, the resist film 15 suppresses that As (arsenic) and P (phosphorus) are introduced into the p-type channel stop region 7. Accordingly, since reduction of height of a potential barrier between pixels 5 adjacent to each other that interpose the channel stop region through the p-type channel stop region 7 due to induction of As (arsenic) and P (phosphorus) into the p-type channel stop region 7 by ion implantation can be suppressed, it is possible to suppress movement of electrons from a prescribed pixel 5 into other adjacent pixel 5 through the p-type channel stop region 7.

In addition, in this embodiment, in ion implantation of P (phosphorus) for forming the n-type intermediate impurity region 11, the ion implantation is conducted by using the resist film 15 which is as a mask same as an ion implantation process of As (arsenic) of the n⁺-type impurity region 12. As a result, since additional resist film is not required to form the n-type intermediate impurity region 11, it is possible to suppress increase in complexity of manufacturing processes.

### EXAMPLE

Comparative simulation (an example and a comparative example) that is performed to confirm effects of the foregoing embodiment is now described. Specifically, comparative simulation that is performed to confirm effects where an n-type intermediate impurity region of an n-type silicon substrate that has a depth larger than a depth of an n⁺-type impurity region and smaller than a depth of an n-type impurity region, and an impurity concentration lower than an impurity concentration of the n⁺-type impurity region and higher than an impurity concentration of the n-type impurity region is formed is described.

First, simulation is performed in the case where a frame transfer type solid-state image sensor according to the example is formed similarly to the foregoing embodiment. That is, in this example, simulation is performed in the case where a frame transfer type solid-state image sensor that has a structure similar to the frame transfer type solid-state image sensor according to the foregoing embodiment shown in FIGS. 3 and 4. In the simulation according to this example, ion implantation of As (arsenic) in the n⁺-type impurity region is set to conditions of implantation energy of 60 keV, and a dose of 2.2×10¹² cm⁻². In addition, ion implantation of P (phosphorus) in the n-type intermediate impurity region is set to conditions of implantation energy of 80 keV, and a dose of 3×10¹¹ cm⁻². Additionally, ion implantation of P (phosphorus) in an n-type impurity region is set to conditions of implantation energy of 150 keV, and a dose of 5×10 cm⁻². Next, simulation is performed in the case where a frame transfer type solid-state image sensor according to the comparative example is formed similarly to the foregoing embodiment except that the n-type intermediate impurity region is not formed. That is, in the comparative example, simulation is performed in the case where a frame transfer type solid-state image sensor having a structure only with an n⁺-type impurity region formed in a region shallower than an n-type impurity region between two p-type channel stop regions adjacent to each other is formed.

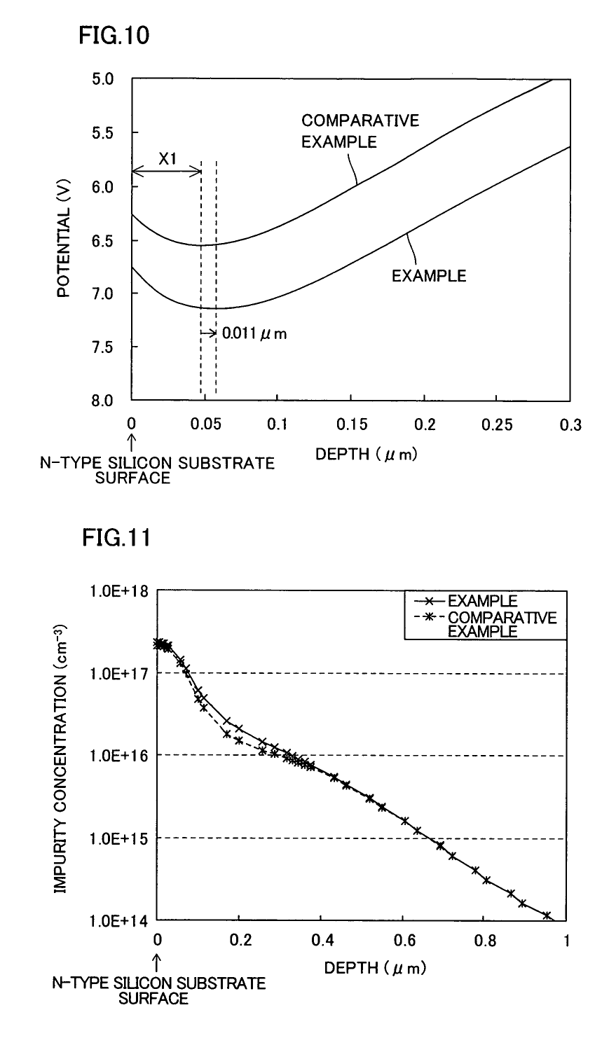

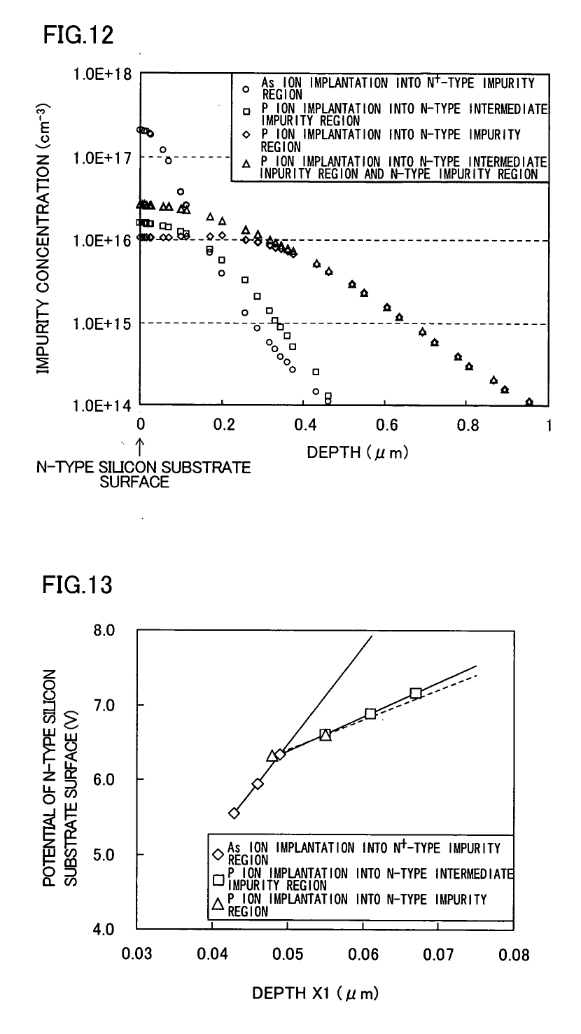

Change of each potential of the solid-state image sensors according to the example and the comparative example against a depth from the surface of the n-type silicon substrate is calculated by simulation. The result is shown in FIG. 10. In addition, change of each impurity concentration of the solid-state image sensors according to the example and the comparative example against a depth from the surface of the n-type silicon substrate is calculated by simulation. The result is shown in FIG. 11. Additionally, change of each impurity concentration of As (arsenic) introduced to the n⁺-type impurity region of the solid-state image sensor according to the example by ion implantation, P (phosphorus) introduced to the n-type intermediate impurity region by ion implantation and P (phosphorus) introduced to the n-type impurity region by ion implantation against a depth from the surface of the n-type silicon substrate are calculated by simulation. The result is shown in FIG. 12.

With reference to FIG. 10, in the example, it is found that a depth X1 of the bottom of a potentially concave portion from the surface of the n-type silicon substrate increases 0.011 μm as compared with the comparative example. In other words, in the example, it is found that the potentially concave portion that stores electrons can be shifted 0.011 μm deeper away from the surface of the n-type silicon substrate as compared with the comparative example. The reason is considered that, as shown in FIG. 11, in the example, the n-type intermediate impurity region is formed in addition to the n⁺-type impurity region and the n-type impurity region, thus, an impurity concentration in the vicinity of the surface of the n-type silicon substrate increases as compared with the comparative example. Furthermore, with reference to FIG. 12, it is found that P (phosphorus) introduced to the n-type intermediate impurity region by ion implantation is introduced into a region deeper than As (arsenic) introduced to the n⁺-type impurity region by ion implantation and shallower than P (phosphorus) introduced to the n-type impurity region by ion implantation. In addition, based on FIG. 12, it is found that P (phosphorus) introduced to the n-type intermediate impurity region by ion implantation has a peak concentration (about 1.6×10¹⁶ cm⁻³) lower than a peak concentration (about 2.0×10¹⁷ cm⁻³) of As (arsenic) introduced to the n⁺-type impurity region by ion implantation and higher than a peak concentration (about 1.1×10¹⁶ cm⁻³) of P (phosphorus) introduced to the n-type impurity region by ion implantation. Additionally, based on FIG. 12, it is found that P (phosphorus) introduced to the n-type intermediate impurity region by ion implantation has the maximum concentration (about 1.6×10¹⁶ cm⁻³) in the surface of the n-type silicon substrate.

Next, simulation is performed in the case where solid-state image sensors are formed. In this case, the depth X1 of the bottom of the potentially concave portion from the surface of the n-type silicon substrate is varied by varying a concentration of As (arsenic) of the n⁺-type impurity region, a concentration of P (phosphorus) of the n-type intermediate impurity region and a concentration of P (phosphorus) of the n-type impurity region by varying implantation amounts of As (arsenic) of the n⁺-type impurity region, P (phosphorus) of the n-type intermediate impurity region and P (phosphorus) of the n-type impurity region, respectively. A potential of the surface of the n-type silicon substrate in each solid-state image sensor is calculated by simulation. FIG. 13 shows a relationship between the potential of the surface of the n-type silicon substrate and the depth X1 of the bottom of the potentially concave portion from the surface of the n-type silicon substrate as calculated above.

With reference to FIG. 13, it is found that an increase rate (gradient) of the potential of the surface of the n-type silicon substrate in the case where the depth X1 of the bottom of the potentially concave portion is increased by increasing P (phosphorus) of the n-type intermediate impurity region is smaller than an increase rate (gradient) of the potential of the surface of the n-type silicon substrate in the case where the depth X1 of the bottom of the potentially concave portion is increased by increasing As (arsenic) of the n⁺-type impurity region. Accordingly, it is found that an increase amount of the potential of the surface of the n-type silicon substrate can be reduced in the case where the potentially concave portion is shifted away from the surface of the n-type silicon substrate by increasing P (phosphorus) of the n-type intermediate impurity region as compared with the case where the potentially concave portion is shifted away from the surface of the n-type silicon substrate by increasing As (arsenic) of the n⁺-type impurity region. Therefore, it is considered that since increase of an electric field that appears in the surface of the n-type silicon substrate due to a gate voltage can be suppressed in the case where the potentially concave portion is shifted away from the surface of the n-type silicon substrate by increasing P (phosphorus) of the n-type intermediate impurity region as compared with the case where the potentially concave portion is shifted away from the surface of the n-type silicon substrate by increasing As (arsenic) of the n⁺-type impurity region, electrons (a dark current) that are thermally excited and pulled out due to the electric field of the surface of the n-type silicon substrate can be reduced. Consequently, it is considered that the potentially concave portion is shifted away from the surface of the n-type silicon substrate preferably by increasing P (phosphorus) of the n-type intermediate impurity region in order to suppress increase of a dark current and to suppress reduction of a frame transfer efficiency of electrons as compared with the case where the potentially concave portion is shifted away from the surface of the n-type silicon substrate by increasing As (arsenic) of the n⁺-type impurity region. In addition, based on FIG. 13, it is found that an increase rate of the potential of the surface of the n-type silicon substrate in the case where the potentially concave portion is shifted away from the surface of the n-type silicon substrate by increasing P (phosphorus) of the n-type intermediate impurity region is almost similar to the case where the potentially concave portion is shifted away from the surface of the n-type silicon substrate by increasing P (phosphorus) of the n-type impurity region.

It should be appreciated, however, that the embodiment and example described above are illustrative, the invention is not specifically limited to description above. The invention is defined not by the foregoing description of the embodiment and example, but by the appended claims, their equivalents, and various modifications that can be made without departing from the scope of the invention as defined in the appended claims.

In the foregoing embodiment, the case where the present invention is applied to a frame transfer type solid-state image sensor is described, however, the present invention is not limited to this case. For example, the present invention is applied to a solid-state image sensor other than a frame transfer type solid-state image sensor.

Furthermore, in the foregoing embodiment, the gate insulating film consisting of SiO₂ is formed, however, the present invention is not limited to this constitution. A gate insulating film containing a material other than SiO₂ may be formed. For example, a gate insulating film may be formed of a SiN film, a multilayer film containing a SiO₂ film and a SiN film.

Furthermore, in the foregoing embodiment, the gate insulating film is formed by a CVD process, however, the present invention is not limited to this process. A gate insulating film may be formed by a process other than a CVD process. For example, a gate insulating film may be formed by a thermal oxidation process.

What is claimed is:

1. A solid-state image sensor comprising:
a semiconductor substrate; and
a charge storage region including a first conductive type first impurity region that has a first depth from a main surface of said semiconductor substrate, a first conductive type second impurity region that has a second depth larger than the first depth of said first impurity region and an impurity concentration lower than an impurity concentration of said first impurity region, and a first conductive type third impurity region that has a third depth larger than the first depth of said first impurity region of said semiconductor substrate and smaller than the second depth of said second impurity region.

2. The solid-state image sensor according to claim 1, wherein the charge storage region including said first, second and third impurity regions is formed in an imaging part.

3. The solid-state image sensor according to claim 1, wherein said third impurity region has an impurity concentration lower than the impurity concentration of said first impurity region and higher than the impurity concentration of said second impurity region.

4. The solid-state image sensor according to claim 3, wherein said first, second and third impurity regions have an n-type conductivity, and
said third impurity region has the n-type impurity concentration lower than the n-type impurity concentration of said first impurity region and higher than the n-type impurity concentration of said second impurity region.

5. The solid-state image sensor according to claim 1, wherein said third impurity region has the maximum impurity concentration in the main surface of said semiconductor substrate.

6. The solid-state image sensor according to claim 1, wherein the sensor further comprises a plurality of second conductive type channel stop regions formed in said semiconductor substrate to make a separation into a plurality of pixels, wherein
said first conductive type first and third impurity regions are formed in a region of said semiconductor substrate other than said second conductive type channel stop regions.

7. The solid-state image sensor according to claim 6, wherein said first conductive type third impurity region is formed between said first conductive type first impurity region and said second conductive type channel stop region.

8. The solid-state image sensor according to claim 6, wherein the second depth of said first conductive type second impurity region is larger than a depth of said second conductive type channel stop region, and
said first conductive type second impurity region is formed not only in a region of said semiconductor substrate where said first and third impurity regions are formed but also in regions of said semiconductor substrate where said second conductive type channel stop regions are formed.

9. The solid-state image sensor according to claim 6, wherein the plurality of said second conductive type channels stop regions are formed so as to extend along a transfer direction of charge and to be spaced at a prescribed interval in a direction that intersects the transfer direction of charge, and
said first conductive type first, second and third impurity regions are formed in a region between said channel stop regions adjacent to each other so as to extend along said transfer direction of charge.

10. The solid-state image sensor according to claim 6, wherein the sensor further comprises a plurality of transfer electrodes that are formed so as to be spaced at a prescribed interval from each other in a transfer direction of charge in regions where said first, second and third impurity regions, and said channel stop regions are formed in the main surface of said semiconductor substrate.

11. The solid-state image sensor according to claim 1, wherein the mass number of a first conductive type impurity contained in said third impurity region is smaller than the mass number of a first conductive type impurity contained in said first impurity region.

12. The solid-state image sensor according to claim 11, wherein the first conductive type impurity contained in said third impurity region is P (phosphorus), and
the first conductive type impurity contained in said first impurity region is As.

13. The solid-state image sensor according to claim 1, wherein said semiconductor substrate has a first conductivity, and a second conductive type fourth impurity region formed so as to have a fourth depth from the main surface of said semiconductor substrate larger than the second depth of the second impurity region of said charge storage region is provided in the main surface of said first conductive type semiconductor substrate, wherein
said first conductive type first, second and third impurity regions are formed in a main surface of said second conductive type fourth impurity region.

14. A solid-state image sensor comprising:
an n-type semiconductor substrate;
a charge storage region including an n-type first impurity region that has a first depth from a main surface of said n-type semiconductor substrate, an n-type second impurity region that has a second depth larger than the first depth of said n-type first impurity region and an impurity concentration lower than an impurity concentration of said n-type first impurity region, and an n-type third impurity region that has a third depth larger than the first depth of said n-type first impurity region and smaller than the second depth of said n-type second impurity region; and
a p-type fourth impurity region formed in the main surface of said n-type semiconductor substrate so as to have a fourth depth from the main surface of said n-type semiconductor substrate larger than the second depth of the second impurity region of said charge storage region.
